(19) United States
(12) Patent Application Publication
(10) Pub. No.: US 2005/0142811 A1
(43) Pub. Date: Jun. 30, 2005

(54) Method for manufacturing semiconductor device

(76) Inventor: Ki Hong Yang, Kyungki-Do (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 10/872,580

(22) Filed: Jun. 21, 2004

(30) Foreign Application Priority Data
Dec. 26, 2003 (KR) 2003-97643

(51) Int. Cl. H01L 21/76; H01L 21/336; H01L 21/31; H01L 21/469

(52) U.S. Cl. 438/439

(57) ABSTRACT

A method for manufacturing a semiconductor device is disclosed. In a disclosed method, a high voltage device and a low voltage device are formed at the same time, before a thermal oxidization process for thickly forming a gate oxide film of a high voltage region, and a bonding structure on the surface of the oxide film in a high voltage region is broken by means of an ion implantation process. In growing the oxide film of an actual high voltage region, the oxide film of the high voltage region can be grown more rapidly than the growth rate by means of heat, thus reducing the bird's beak. Therefore, since a depletion region at the PN junction is increased, the CCST properties can be improved.

### BACKGROUND

1. Field of the Invention

The present invention relates to a method for manufacturing a semiconductor device, and more specifically, to a method for manufacturing a semiconductor device in which gate oxide films of a different thickness are formed in a high voltage region and a low voltage region, respectively.

2. Discussion of Related Art

A method for manufacturing a semiconductor device in which gate oxide films of a different thickness are formed in a high voltage region and a low voltage region, respectively, will be described with reference to FIG. 1A to FIG. 1C.

Referring to FIG. 1A, a first oxide film 12, a nitride film 13 and a second oxide film 14 are sequentially formed on a semiconductor substrate 11. In the above, the first oxide film 12 is formed in thickness of about 50 Å, the nitride film 13 is formed in thickness of about 200 Å and the second oxide film 14 is formed in thickness of about 100 Å. A photoresist film (not shown) through which a high voltage region A is exposed and a low voltage region B is closed is then formed on the entire structure. The second oxide film 14 and the nitride film 13 in the high voltage region A are then stripped by means of a wet etch process using the photoresist film as a mask.

By reference to FIG. 1B, a pre-cleaning process is performed. A thermal oxidization process is then implemented to grow an oxide film in the high voltage region A, thus forming a gate oxide film 12A.

Referring to FIG. 1C, the second oxide film 14 and the nitride film 13 remaining in the low voltage region B are stripped and the first oxide film 12 of the high voltage region A is then recessed. Thus a thick gate oxide film 12A is formed in the high voltage region A and a thin gate oxide film 12B is formed in the low voltage region B.

However, the bird's beak is formed at a portion 10 where the gate oxide film of the high voltage region A whose thickness is increased by the thermal oxidization process and the gate oxide film of the low voltage region B come in contact with each other. Thus, there is lots of variation in CCST (Constant Current Stress Test) between the high voltage region A and the low voltage region B. Furthermore, in view of the electrical properties, there is a problem in reliability of a device due to generation of hump. Accordingly, lots of time is taken when charges are transferred. It is thus difficult to reduce a response time when a signal is applied.

### SUMMARY OF THE INVENTION

The present invention is directed to a method for manufacturing a semiconductor device that can reduce the bird's beak occurring in a portion where gate oxide films of a high voltage region and a low voltage region come in contact with each other.

Another object of the present invention is to provide a method for manufacturing a semiconductor device wherein the bird's beak is reduced because an oxide film of a high voltage region is more rapidly grown than the growth rate by means of heat in growing the oxide film of an actual high voltage region, in such a way that before a thermal oxidization process is performed, an ion implantation process is implemented for the high voltage region, thus broking a bonding structure on the surface of the oxide film in the high voltage region.

According to an aspect of the present invention, there is provided a method of manufacturing a semiconductor device, comprising the steps of: sequentially forming a first oxide film, a nitride film and a second oxide film on a semiconductor substrate; selectively removing the second oxide film and the nitride film, wherein a low voltage device region of the first oxide film is covered with the nitride film and the second oxide film, and a high voltage device region of the first oxide film is exposed; breaking a bond structure on a surface of the second region of the first oxide film by performing an ion implantation process; performing a thermal oxidization process to grow a third oxide film on the exposed portion of the first oxide film; and exposing the first region of the first oxide film by removing the second oxide film and the nitride film, and recessing a part of the third oxide film, thus forming a first gate oxide film with the first region of the first oxide film and a second gate oxide film with the second region of the first oxide film and the third oxide film remaining on the second region of the first oxide film.

According to another aspect of the present invention, there is provided a method of manufacturing a semiconductor device, comprising the steps of: sequentially forming a first oxide film, a nitride film and a second oxide film on a semiconductor substrate; selectively removing the second oxide film and the nitride film, wherein a low voltage device region of the first oxide film is covered with the nitride film and the second oxide film, and a high voltage device region of the first oxide film is exposed; breaking a bond structure on a surface of the second region of the first oxide film by performing an ion implantation process; performing a thermal oxidization process to grow a third oxide film on the exposed portion of the first oxide film; and exposing the first region of the first oxide film by removing the second oxide film and the nitride film, and recessing a part of the third oxide film, thus forming a first gate oxide film with the first region of the first oxide film and a second gate oxide film with the second region of the first oxide film and the third oxide film remaining on the second region of the first oxide film.

The ion implantation process is performed using BF₂, phosphorous (P) or arsenic (As).

According to another aspect of the present invention, there is provided a method of manufacturing a semiconductor device, comprising the steps of sequentially forming a first oxide film, a nitride film and a second oxide film on a semiconductor substrate; stripping the second oxide film and the nitride film in the first region to expose the first oxide film; performing an ion implantation process to break a bonding structure on the surface of the first oxide film in the first region; performing a thermal oxidization process to grow the first oxide film of the first region; and stripping the second oxide film and the nitride film of the second region, and then recessing the grown first oxide film to form the gate oxide films of a different thickness in the first region and the second region, respectively.

The first region is a region where a high voltage device is formed, and the second region is a region where a low voltage device is formed.

The ion implantation process is formed using BF₂, phosphorous (P) or arsenic (As).

### BRIEF DESCRIPTION OF THE DRAWINGS

FIG. 1A to FIG. 1C are cross-sectional views sequentially shown to explain a method for manufacturing a semiconductor device in which gate oxide films of a different thickness are formed in a high voltage region and a low voltage region, respectively, in the related art:

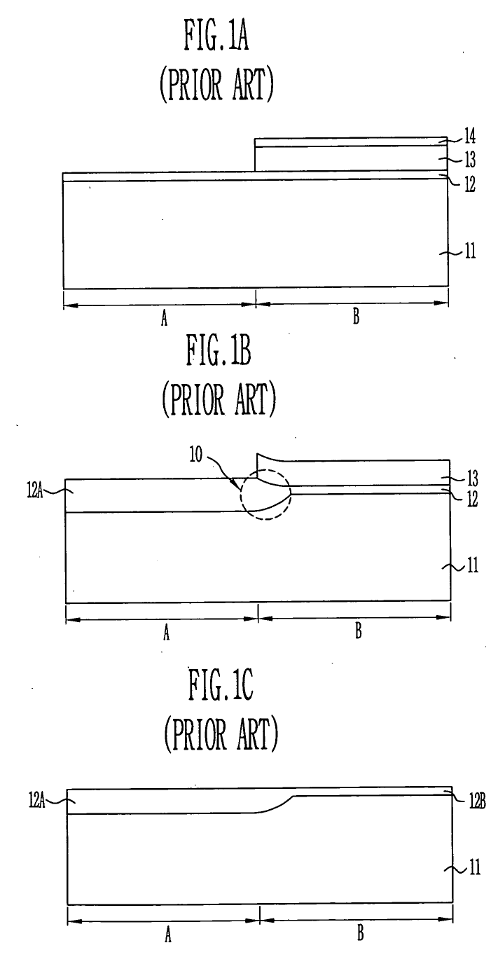

FIG. 2A to FIG. 2D are cross-sectional views sequentially shown to explain a method for manufacturing a semiconductor device in which gate oxide films of a different thickness are formed in a high voltage region and a low voltage region, respectively, according to an embodiment of the present invention;

FIG. 3 is a graph showing a comparison result of CSCT in case where the gate oxide film is formed by a conventional method and a method of the present invention; and

FIG. 4 is a graph showing a comparison result of C-V stress in case where the gate oxide film is formed by a conventional method and a method of the present invention.

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later. Like reference numerals are used to identify the same or similar parts.

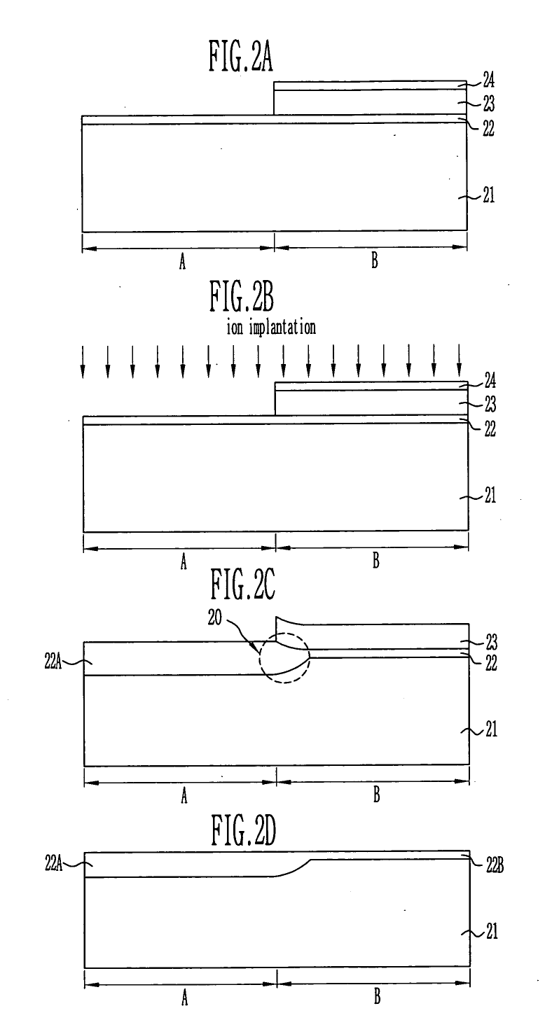

FIG. 2A to FIG. 2D are cross-sectional views sequentially shown to explain a method for manufacturing a semiconductor device in which gate oxide films of a different thickness are formed in a high voltage region and a low voltage region, respectively, according to the present invention.

Referring to FIG. 2A, a first oxide film 22, a nitride film 23 and a second oxide film 24 are sequentially formed on a semiconductor substrate 21. In the above, the first oxide film 22 is formed in thickness of about 50 Å, the nitride film 23 is formed in thickness of about 200 Å and the second oxide film 24 is formed in thickness of about 100 Å. A photoresist film (not shown) through which a high voltage region A is exposed and a low voltage region B is closed is then formed on the entire structure. The second oxide film 24 and the nitride film 23 in the high voltage region A are then stripped by means of a wet etch process using the photoresist film as a mask.

By reference to FIG. 2B, an ion implantation process is implemented to break a bonding structure on the surface of the first oxide film 22 in the high voltage device region A. In the above, the ion implantation process is performed using BF₂, phosphorous (P) or arsenic (As).

Referring to FIG. 2C, a pre-cleaning process is performed. A thermal oxidization process is then implemented to grow the first oxide film 22 of a predetermined thickness in the high voltage region A. In this case, the first oxide film 22 in the high voltage device region A has its bonding structure broken by means of the ion implantation process. Thus, the first oxide film 22 in the high voltage device region A can be grown more rapidly than the growth rate by heat. By doing so, the bird's beak can be reduced at a portion 20 where the first oxide film 22 of the high voltage region A and the low voltage region B come in contact with each other.

Referring to FIG. 2D, the second oxide film 24 and the nitride film 23 remaining in the low voltage region B are stripped and the first oxide film 22 of the high voltage region A is then recessed. Thus a thick gate oxide film 22A is formed in the high voltage region A and a thin gate oxide film 22B is formed in the low voltage region B.

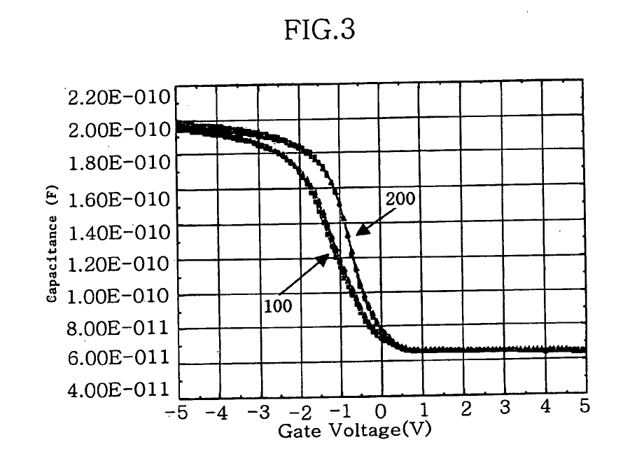

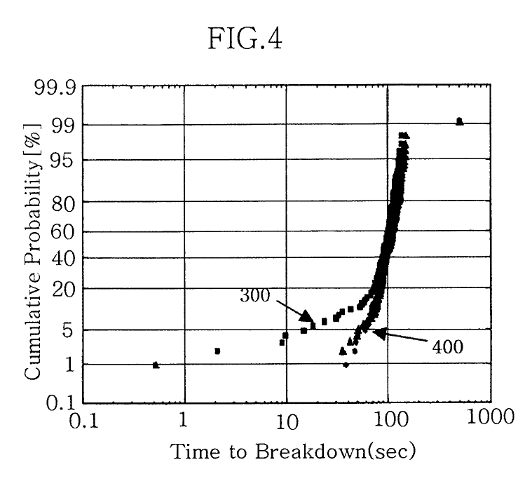

FIG. 3 is a graph showing a comparison result of CSCT in case where the gate oxide film is formed by a conventional method 100 and a method of the present invention 200, and FIG. 4 is a graph showing a comparison result of C-V stress in case where the gate oxide film is formed by a conventional method 300 and a method of the present invention 400.

According to the present invention described above, before a thermal oxidization process for thickly forming a gate oxide film of a high voltage region is performed, an ion implantation process is performed to break a bonding structure on the surface of the oxide film in the high voltage region. In growing the oxide film of an actual high voltage region, the oxide film of the high voltage region can be grown more rapidly than the growth rate by means of heat, thus reducing the bird's beak. Therefore, since a depletion region at the PN junction of a transistor is increased, the CCST properties can be improved. Furthermore, it is possible to reduce or obviate the effects due to hump occurring between the high voltage region and the low voltage region. It is also possible to reduce time taken when charges are transferred due to reduction in the bird's beak.

1. A method of manufacturing a semiconductor device comprising:
sequentially forming a first oxide film, a nitride film and a second oxide film on a semiconductor substrate;
selectively removing a portion of the second oxide film and the nitride film to leave a first region of the first oxide film is covered with the nitride film and the second oxide film and a second region of the first oxide film is exposed;
performing an ion implantation process;
performing a thermal oxidization process to grow a third oxide film on the exposed second region of the first oxide film to form a third oxide film on the second region of the first oxide film; and
exposing the region of the first oxide film by removing the second oxide film and the nitride film, and recessing a portion of the third oxide film to a first gate oxide film with the first region of the first oxide film and a second gate oxide film with the second region of the first oxide film and the third oxide film remaining on the second region of the first oxide film.

2. The method as claimed in claim 1, wherein the ion implantation process is performed using BF₂, phosphorous (P) or arsenic (As).

3. The method as claimed in claim 1, wherein the first region is a region where a low voltage device is formed, and the second region is a region where a high voltage device is formed.

4. A method of manufacturing a semiconductor device comprising:
sequentially forming a first oxide film, a nitride film and a second oxide film on a semiconductor substrate;
selectively removing the second oxide film and the nitride film to leave a low voltage region of the first oxide film covered with the nitride film and the second oxide film and to expose a high voltage region of the first oxide film;
breaking a bond structure on a surface of the high voltage region of the first oxide film by performing an ion implantation process;
performing a thermal oxidization process to grow the high voltage region of the first oxide film so that a third oxide film is formed thereon; and
exposing the low voltage region of the first oxide film by removing the second oxide film and the nitride film, and recessing a part of the third oxide film, thus forming a first gate oxide film from the low voltage region of the first oxide film and a second gate oxide film from the high voltage region of the first oxide film and the third oxide film remaining on the high voltage region of the first oxide film.

5. The method as claimed in claim 4, wherein the ion implantation process is performed using BF₂, phosphorous (P) or arsenic (As).
